(19) United States
(12) Patent Application Publication
(10) Pub. No.: US 2025/0298670 A1
(43) Pub. Date: Sep. 25, 2025

(54) REAL-TIME OPTIMIZATION OF APPLICATION PERFORMANCE AND RESOURCE MANAGEMENT

(71) Applicant: INTERNATIONAL BUSINESS MACHINES CORPORATION, Armonk, NY (US)

(72) Inventors: Yong Chao Li, Shanghai (CN); Gu Juan, Yancheng city (CN); Xiao Wei XW Gao, BEIJING (CN); Wei Shan, Shanghai (CN); Hai Qun Tang, SHANGHAI (CN); Jia Ning Li, Shanghai (CN)

(21) Appl. No.: 18/609,519

(22) Filed: Mar. 19, 2024

(51) Int. Cl. G06F 9/50; G06F 30/27

(52) U.S. Cl. CPC G06F 9/505; G06F 30/27

(57) ABSTRACT

Embodiments compare key metrics data representing real-time workloads performed by a computer set representing one or more containers; determine that the key metrics data does not key metrics criteria; in response to the determining, query, from a pre-trained look up table, an optimal configuration for deploying resources to at least one containerized application of the computer set; determine that the optimal configuration is not found from the pre-trained look up table; train a neural network (NN) model by using samples from the pre-trained look up table as training data; determine the optimal configuration using the trained NN model; and deploy the determined optimal configuration for the computer set.

### BACKGROUND

In current systems, multiple applications run together in a single cluster with the goal of meeting service level objectives (SLOs) at a reasonable cost. For example, the single cluster comprises multiple parallel applications that flexibly share data within the single cluster. The present embodiments relate to containers of software in and for computers, computing resource analysis, and artificial intelligence for improving usage of computing resources.

### SUMMARY

In a first aspect of the present invention, there is a computer-implemented method including: comparing, by a processor set, key metrics data representing real-time workloads performed by a computer set comprising one or more containers; determining, by the processor set, that the key metrics data does not meet key metrics criteria; in response to the determining, querying, by the processor set, from a pre-trained look table, an optimal configuration for deploying resources to at least one containerized application of the computer set; determining, by the processor set, that the optimal configuration is not found from the pre-trained look up table; training, by the processor set, a neural network (NN) model by using samples from the pre-trained look up table as training data; determining, by the processor set, the optimal configuration using the trained NN model; and deploying, by the processor set, the determined optimal configuration for the computer set.

In another aspect of the present invention, there is a computer program product including one or more computer readable storage media having program instructions collectively stored on the one or more computer readable storage media. The program instructions are executable to: receive real time workloads from an external system; determine that key metrics criteria of the real-time workloads have not been achieved; query an optimal configuration from a pre-trained look up table; determine that the optimal configuration is not from the pre-trained look up table; load samples from the pre-trained look up table; train a neural network (NN) model based on the loaded samples from the pre-trained look up tables; determine the optimal configuration using the trained NN model; and deploy the determined optimal configuration for providing resources to at least one containerized application in a containerized system.

In another aspect of the present invention, there is a system including a processor set, one or more computer readable storage media, and program instructions, collectively stored on the one or more computer readable storage media, for causing the processor set to: receive simulated workloads from an external system, the simulated workloads simulating performance of at least one containerized application; train a reinforcement learning model based on the simulated workloads; determine one or more optimal configurations using the trained reinforcement learning model and the simulated workloads; and store entries representing the one or more optimal configurations i a pre-trained look up table. In further aspects of the present invention, the simulated workloads produce pre-production data which includes data that is used for performance evaluation and testing, and the pre-trained look up table is accessible for providing recommendations for configurations for applying computing resources to a containerized application.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 depicts a computing environment according to an embodiment of the present invention.

FIG. 2 shows a block diagram of an exemplary environment of a containerized system in accordance with aspects of the present invention.

FIG. 3 shows an example of a Q table of at least one simulated workload in accordance with aspects of the present invention.

FIG. 4 shows an example of a pre-trained look up table of the at least one simulated workload in accordance with aspects of the present invention.

FIG. 5 shows a flowchart of an exemplary method in accordance with aspects of the present invention.

FIG. 6 shows a flowchart of another exemplary method in accordance with aspects of the present invention.

### DETAILED DESCRIPTION

Aspects of the present invention relate generally to real-time optimization of application performance and resource management. Embodiments of the present invention provide an auto scaler process for dynamically tuning performance with resource limits for a containerized application. Aspects of the present invention also provide horizontal resource optimization and vertical resource optimization for an application. In embodiments of the present invention, horizontal resource optimization refers to scaling a workload to match demand and vertical resource optimization refers to assigning additional resources for a current workload. Implementations of the present invention also integrate a service topology into an initial model, utilize reinforcement learning to train at least one model, and construct a look up table in a pre-production environment. In this manner, embodiments of the present invention leverage the look up table to recommend an optimal configuration in a real-time production environment by either selecting a closest configuration or using a small neural network to recommend the optimal configuration. In accordance with aspects of the present invention, a reinforcement model is built and trained using continuous feedback data from a production environment. In further embodiments, the trained reinforcement model is able to update the look up table based on the continuous feedback data from the production environment.

Embodiments of the present invention provide an application-level optimization in a production environment using an accurate and fully automated approach. Aspects of the present invention continuously optimize and refine the trained reinforcement model and the look up table based on feedback data in the production environment. Aspects of the present invention also provide candidate actions using reinforcement learning (e.g., Q learning) based on service topology and monitoring data in a pre-production environment. Accordingly, embodiments of the present invention accelerate the reinforcement learning process and improve an accuracy of finding the optimal configuration in comparison to conventional systems.

Embodiments of the present invention provide a computer-implemented method, a system, and a computer program product for implementing an automated real-time optimized configuration. In contrast, conventional systems merely performs horizontal auto scaling at a pod level, which is a slower scaling process than the present invention because multiple pods need to be scheduled and scaled for an application. Further, conventional systems are not able to optimize application resources and find bottlenecks which affect application performance. Further, conventional systems are not able to optimize application resources in a dynamic and automated process. In contrast, embodiments of the present invention provided automated performance tuning for enhancing application efficiency and reliability. Aspects of the present invention also eliminate manual processes and reduce errors by using machine learning (ML) technology and optimization algorithms to enable dynamic scaling of application resources and application performance improvements.

Embodiments of the present invention include a highly computationally efficient system, method, and computer program product for providing an optimized configuration for real-time workloads. Accordingly, implementations of the present invention provide an improvement (i.e., technical solution) to a problem arising in the technical field of providing an optimized configuration for a containerized application. In particular, embodiments of the present invention provide reinforcement learning to build and train a reinforcement model for providing an optimized configuration to a look up table. Embodiments of the present invention also provide a neural network (NN) algorithm to build and train a NN model for providing the optimized configuration.

Implementations of the present invention are necessarily rooted in computer technology. For example, the steps of training, by the processor set, a reinforcement model and a neural network (NN) model based on simulated workloads and real-time workloads, respectively, are computer-based and cannot be performed in the human mind. Training and building the reinforcement model and the NN model are, by definition, performed by a computer and cannot practically be performed in the human mind (or with pen and paper) due to the complexity and massive amounts of calculations involved. For example, training and building the reinforcement model and the NN model in embodiments of the present invention includes using machine learning to build and train the reinforcement model and the NN model using simulated and real-time workloads to improve the accuracy of an application level optimization within a containerized system. In particular, training and building the reinforcement model and the NN model use a large amount of processing of simulated and real-time workloads and modeling of parameters to train the reinforcement model and the NN model such that the reinforcement model and the NN model generate and output an optimized configuration in real time (or near real time). Given the scale and complexity of processing simulated and real-time workloads and modeling of parameters, it is simply not possible for the human mind, or for a person using pen and paper, to perform the number of calculations involved in training and/or building the reinforcement model and the NN model.

Aspects of the present invention include a method, system, and computer program product for providing an optimized configuration for real-time workloads. For example, a computer-implemented method includes: providing an auto scale method to dynamically tune a performance with resource limits for a containerized application; providing horizontal and vertical resource optimization for the containerized application; integrating service topology into an initial model and use reinforcement machine learning to train a series of models and construct a look up table in a pre-production environment; leveraging the look up table to quickly recommend a real-time optional configuration in production environment by either selecting the closest option within the look up table or using a small neural network; and enriching and refining the look up table and update pre-trained model using the feedback data continuously gathered from the production environment.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as application level scaling code of block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

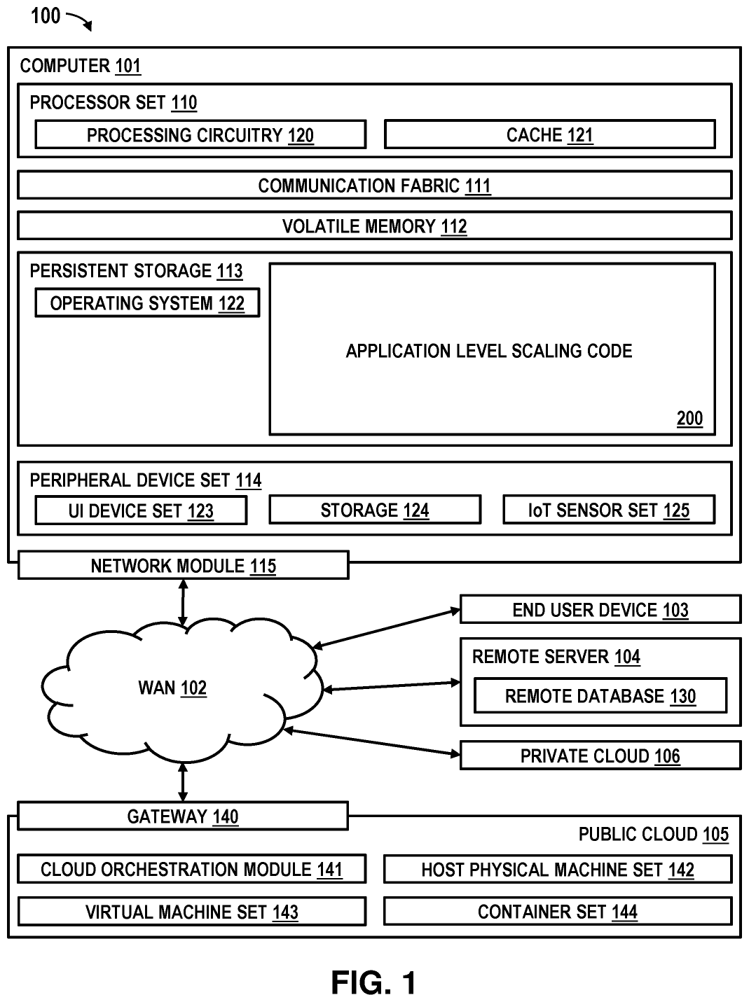

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

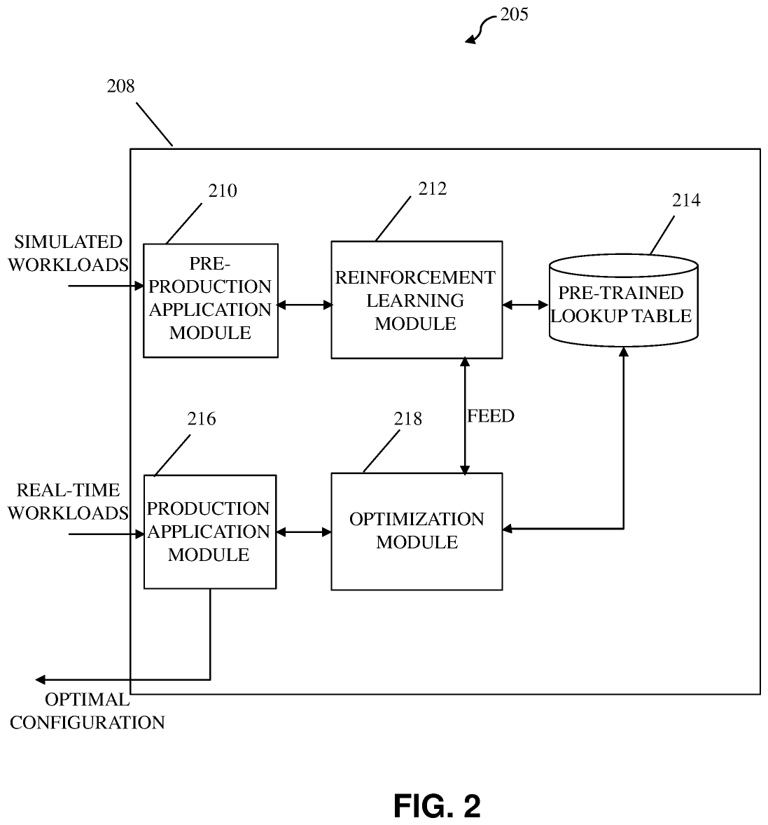

FIG. 2 shows a block diagram of an exemplary environment 205 of a containerized system in accordance with aspects of the present invention. In embodiments, the environment 205 of the containerized system includes an application level scaling server 208, which may comprise one or more instances of the computer 101 of FIG. 1. In other examples, the application level scaling server 208 comprises one or more virtual machines or one or more containers running on one or more instances of the computer 101 of FIG. 1.

In embodiments, the application level scaling server 208 of FIG. 2 comprises a pre-production application module 210, a reinforcement learning module 212, a pre-trained look up table 214, a production application module 216, and an optimization module 218, each of which may comprise modules of the code of block 200 of FIG. 1. Such modules may include routines, programs, objects, components, logic, data structures, and so on that perform particular tasks or implement particular data types that the code of block 200 uses to carry out the functions and/or methodologies of embodiments of the present invention as described herein. These modules of the code of block 200 are executable by the processing circuitry 120 of FIG. 1 to perform the inventive methods as described herein. The application level scaling server 208 may include additional or fewer modules than those shown in FIG. 2. In embodiments, separate modules may be integrated into a single module. Additionally, or alternatively, a single module may be implemented as multiple modules. Moreover, the quantity of devices and/or networks in the environment is not limited to what is shown in FIG. 2. In practice, the environment may include additional devices and/or networks; fewer devices and/or networks; different devices and/or networks; or differently arranged devices and/or networks than illustrated in FIG. 2.

In accordance with aspects of the present invention, the pre-production application module 210 receives simulated workloads from an external system, e.g., customer computing system in a customer computing environment. In embodiments, a workload comprises at least one computational task that is executed by a containerized application in one or more computer systems. In further embodiments, the workload can be a simulated workload in a pre-production environment or a real-time workload in a production environment. In embodiments, the pre-production application module 210 comprises a pre-production application which runs the simulated workloads and collects pre-production telemetry data including key metrics data and a service topology from the simulated workloads and sends the key metrics data and the service topology to the reinforcement learning module 212. In further embodiments, the simulated workloads comprise pre-production data and the service topology comprises a relationship between simulated application components within the containerized system. In aspects of the present invention, the pre-production data comprises data that is used for performance evaluation and testing within a pre-production environment used to develop and test the simulated workloads.

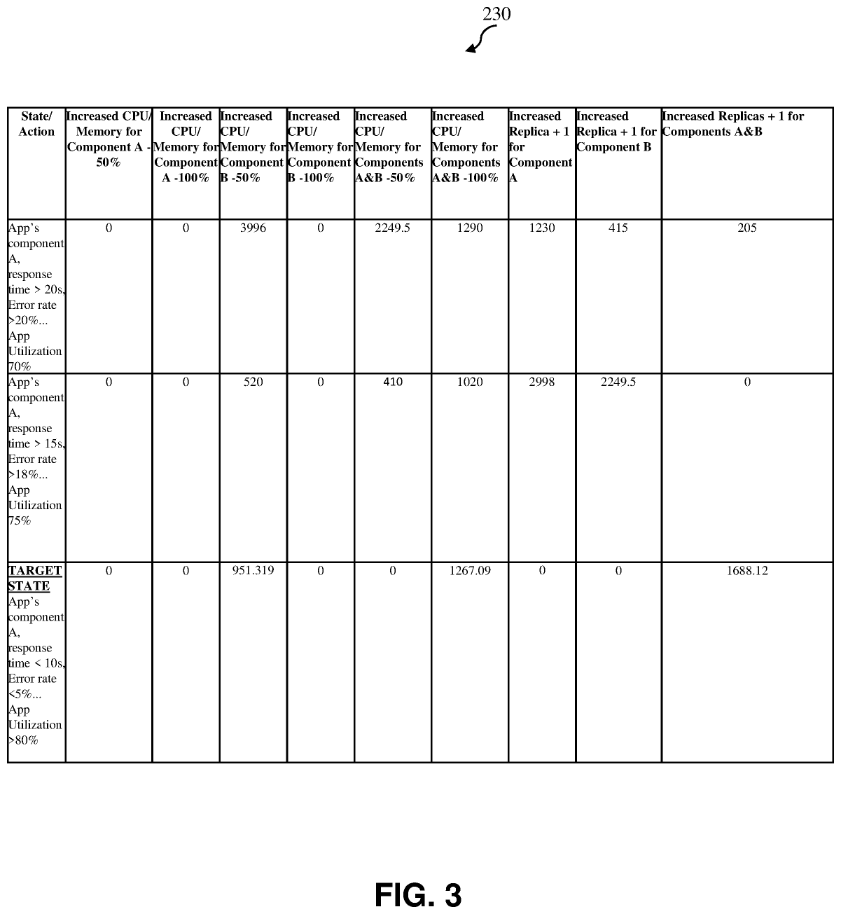

In reference to FIG. 2, the reinforcement learning module 212 receives the key metrics data and the service topology and builds and trains a reinforcement model based on the key metrics data and the service topology of the simulated workloads. In particular, the reinforcement learning module 212 uses a reinforcement algorithm to build and train the reinforcement model to find an optimal configuration which includes tuning actions to meet a service level objective (SLO) of a target state. In embodiments, the optimal configuration comprises a resource configuration (e.g., CPU, memory, replicas) for supporting a containerized application in one or more computer systems. The reinforcement model acts as an intelligent agent to decide how to take actions in a dynamic environment in order to maximize the cumulative reward. In embodiments of the present invention, the optimal configuration found by the reinforcement model comprises a configuration which provides a dynamic tuning of performance with resource limits to provide a horizontal and vertical resource optimization for a target workload within a containerized application. In aspects of the present invention, the reinforcement learning module 212 sends the optimal configuration to the pre-production application module 210. In further embodiments, the reinforcement learning module 212 uses a Q learning algorithm to find the optimal configuration by maximizing an expected value of a total reward over all successive steps starting from a current state. In aspects of the present invention, the Q learning algorithm dynamically captures states based on the key metrics data of the simulated workloads and dynamically generates action lists based on the key metrics data and the service topology of the simulated workloads. In further embodiments, the Q learning algorithm creates a Q table 230 based on the dynamically captured states and the generated actions lists. An example of the Q table 230 is further described in FIG. 3.

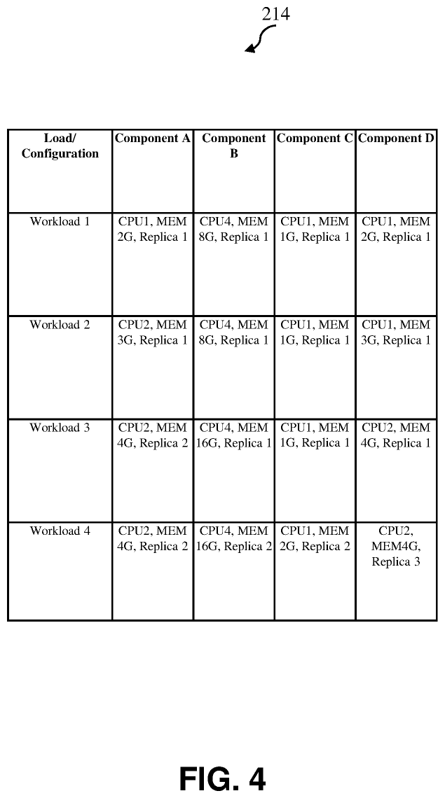

In embodiments of FIG. 2, the reinforcement learning module 212 generates the optimal configuration for a target workload based on an original application configuration and the generated action lists and the dynamically captured states in the Q table 230. The reinforcement learning module 212 then sends the optimal configuration for the target workload to a pre-trained look up table 214 and causes an entry to be created in the pre-trained look up table 214. Information representing the optimal configuration is stored in the entry that is created. An example of the pre-trained look up table 214 is further described in FIG. 4.

According to aspects of the present invention, the production application module 216 receives the real-time workloads from the external system, e.g., the customer computing system in the customer computing environment. In embodiments, the production application module 216 comprises a production application which runs the real-time workloads and collects production telemetry data including key metrics data from the real-time workloads and sends the key metrics data to the optimization module 218. In further embodiments, the real-time workloads comprise production data. In aspects of the present invention, the production data comprises real-time data that is used for customers within a production environment used to run the real-time workloads

In further reference to FIG. 2, the optimization module 218 determines whether key metrics criteria of the real-time workloads have been achieved based on the key metrics data from the real-time workloads. The optimization module 218 also determines whether resource utilization is low in response to a determination that the key metrics criteria of the real-time workloads have been achieved. The optimization module 218 then determines the optimal configuration in response to a determination that the resource utilization is not low. The optimization module 218 queries an optimal configuration from a pre-trained look up table 214 in response to a determination that the key metrics criteria of the real-time workloads have not been achieved. In further embodiments, the optimization module 218 queries the optimal configuration from the pre-trained look up table 214 in response to a determination that the resource utilization is low.

In aspects of the present invention in FIG. 2, the optimization module 218 determines whether the optimal configuration is found from the pre-trained look up table 214. In particular, the optimization module 218 determines that the optimal configuration is found from the pre-trained look up table 214 by determining that a numerical value representing the simulated workload associated with the optimal configuration in the pre-trained look up table 214 is within a predetermined threshold value of the received real-time workloads. The optimization module 218 then determines the optimal configuration is found and applies the determined optimal configuration to the real-time workloads in response to a determination that the numerical value representing the simulated workload associated with the optimal configuration in the pre-trained look up table 214 is within a predetermined threshold value of the received real-time workloads.

In further embodiments of FIG. 2, the optimization module 218 determines that the optimal configuration is not found from the pre-trained look up table 214 by determining that the numerical value representing simulated workload associated with the optimal configuration in the pre-trained look up table 214 is greater than the predetermined threshold value of the received real-time workloads. In further embodiments, the optimization module 218 then loads samples of optimal configurations from the pre-trained look up table 214 which have a numerical value that is greater than the predetermined threshold value of the received real-time workloads and have the numerical value that is less than a maximum threshold value of the received real-time workloads. In aspects of the present invention, the values of the predetermined threshold value and the maximum threshold value can be user configured.

In implementations of the present invention in FIG. 2, the optimization module 218 builds and trains a neural network (NN) model based on the loaded samples of optimal configurations from the pre-trained look up table 214. Accordingly, the optimization module 218 utilizes the trained NN model to determine an optimal configuration based on the loaded samples of optimal configurations from the pre-trained look up table 214. Then, the optimization module 218 applies the determined optimal configuration to the real-time workloads.

In accordance with aspects of the present invention, the optimization module 218 leverages the pre-trained look up table 214 to quickly recommend a real-time optimal configuration in a production environment. In an aspect of the present invention, the optimization module 218 leverages the pre-trained look up table 214 to quickly recommend the real-time optimal configuration by querying for a matched load (i.e., simulated workload which is matched to a real-time workload based on a difference between the numerical values of the simulated workload and the real-time workload being less than a predetermined threshold value) within the pre-trained look up table 214 and applying the recommended real-time optimal configuration which is associated with the matched load (i.e., simulated workload which is matched) to the real-time workload. In another aspect of the present invention, the optimization module 218 trains a small neural network (NN) with training data that includes samples from the pre-trained look up table 214 (i.e., the samples include the simulated workloads which have a difference in a numerical value to the real-time workload that is greater than the predetermined threshold value and is less than a maximum threshold value). In various embodiments, this training data is used for supervised learning of the neural network, where certain portions of the information regarding the simulated workloads is used as input for the neural network and is used to predict other portions of the same simulated workload (the other portions being predicted are the labels for the supervised training). For example, the neural network is trained in various embodiments to include application type and/or partial component information in order to predict other or all computing configurations for the various components of the containerized application. In further embodiments, the optimization module 218 utilizes the NN model to recommend the real-time optimal configuration for the real-time workload using the samples, and then applies the real-time optimal configuration to the real-time workload. In further embodiments, the optimization module 218 feeds the real-time optimal configuration to the reinforcement learning module 212. The reinforcement learning module 212 in some embodiments sends the real-time optimal configuration (or information representing same) to the pre-trained lookup table 214 to cause an entry to be generated therein to store the information representing this real-time optimal configuration.

FIG. 3 shows an example of a Q table of the simulated workloads in accordance with aspects of the present invention. In embodiments, the reinforcement learning module 212 uses a Q learning algorithm to create the Q table 230 of the simulated workloads. The Q table 230 includes various states in the first column (e.g., App's component A, response time >20 s, Error rate >20% . . . . App Utilization 70%) and various actions, that correspond to the respective states, in the rows (e.g., increased CPU Memory for component A—50%). The last row is the target state (e.g., App's component A, response time <10 s, Error rate <5% . . . App Utilization >80%) which achieves a required service level objective (SLO). The values in each column (e.g., 3996, 2249.5, 1290, etc.) are reward scores corresponding to the intersection of the state and the action. For example, in the Q table 230, for the state of App's component A, response time >20 s, Error rate >20% . . . . App Utilization 70% and the action of Increased CPU/Memory for component B—50%, a reward score of 3996 is generated. Thus, increasing CPU/Memory for component B by 50% gives a good reward score of 3996. In contrast, in the Q table 230, for the state of App's component A, response time >20 s, Error rate >20% . . . . App Utilization 70% and the action of Increased CPU/Memory for component A-50%, a reward score of 0 is generated. Accordingly, as shown in the Q table 230, increasing CPU/Memory for component A by 50% doesn't generate any positive reward. In further embodiments, the reward scores in the Q table 230 identify a path that achieves a good reward score. In some embodiments, the Q-learning algorithm uses the reward scores in the Q table 230 to identify certain paths within the Q table 230 in order to determine an optimal configuration for resources for a containerized application.

FIG. 4 shows an example of a pre-trained look up table in accordance with aspects of the present invention. In embodiments, the reinforcement learning module 212 sends the optimal configuration for the target workload to the pre-trained look up table 214 using information contained in the Q table 230. As an example, the pre-trained look up table 214 includes an optimal configuration for workload 1 which includes CPU1, MEM 2G, Replica 1 for component A, CPU4, MEM 8G, Replica 1 for component B, CPU1, MEM 1G, Replica 1 for component C, and CPU1, MEM 2G, Replica 1 for component D. Thus, this optimal configuration for workload 1 is stored in the pre-trained look up table 214. In further embodiments, in response to the optimization module 218 determining that the numerical value representing real-time workloads is within a predetermined threshold value of the workload 1, the optimization module 218 determines that the optimal configuration is found in the pre-trained look up table 214 (i.e., the optimal configuration for workload 1). Accordingly, the optimization module 218 can apply this optimal configuration (i.e., the optimal configuration for workload 1) to the real-time workloads so that application resources are optimized in a dynamic and automated process. In further embodiments, each workload of the workload 1, workload 2, workload 3, and workload 4 in the pre-trained look up table is measured by a vector of transactions per second or minute, by a vector representing all entries or key entries, and/or by critical endpoints in production and non-production environments.

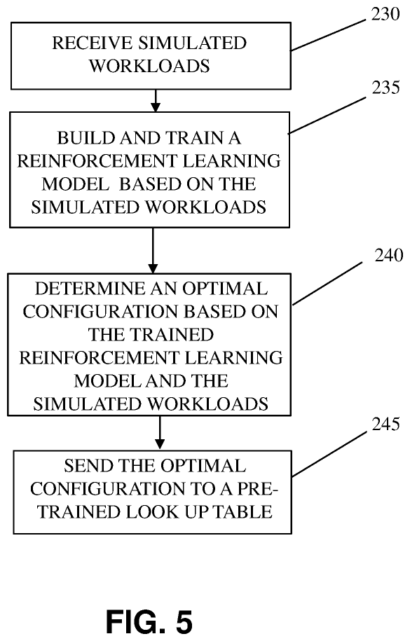

FIG. 5 shows a flowchart of an exemplary method in accordance with aspects of the present invention. Steps of the method may be carried out in the environment of FIG. 2 and are described with reference to elements depicted in FIG. 2.

At step 230, the system receives, at the pre-production application module 210, simulated workloads from an external system. In embodiments and as described with FIG. 2, the pre-production application module 210 comprises a pre-production application which runs the simulated workloads and collects pre-production telemetry data including key metrics data and a service topology from the simulated workloads and sends the key metrics data and the service topology to the reinforcement learning module 212.

At step 235, the system builds and trains, at the reinforcement learning module 212, a reinforcement model based on the simulated workloads. In embodiments and as described with FIG. 2, the reinforcement learning module 212 uses a reinforcement algorithm to build and train the reinforcement model based on key metrics and the service topology of the simulated workloads to find an optimal configuration which includes tunings actions to meet a service level objective (SLO) of a target state.

At step 240, the system determines, at the reinforcement learning module 212, an optimal configuration based on the trained reinforcement model and the simulated workloads. In embodiments and as described with FIG. 2, the reinforcement learning module 212 sends the optimal configuration to the pre-production application module 210. At step 245, the system sends, at the reinforcement learning module 212, the optimal configuration to a pre-trained look up table 214. This sending causes one or more entries to be generated in the pre-trained lookup table 214 in order to store this information representing this optimal configuration.

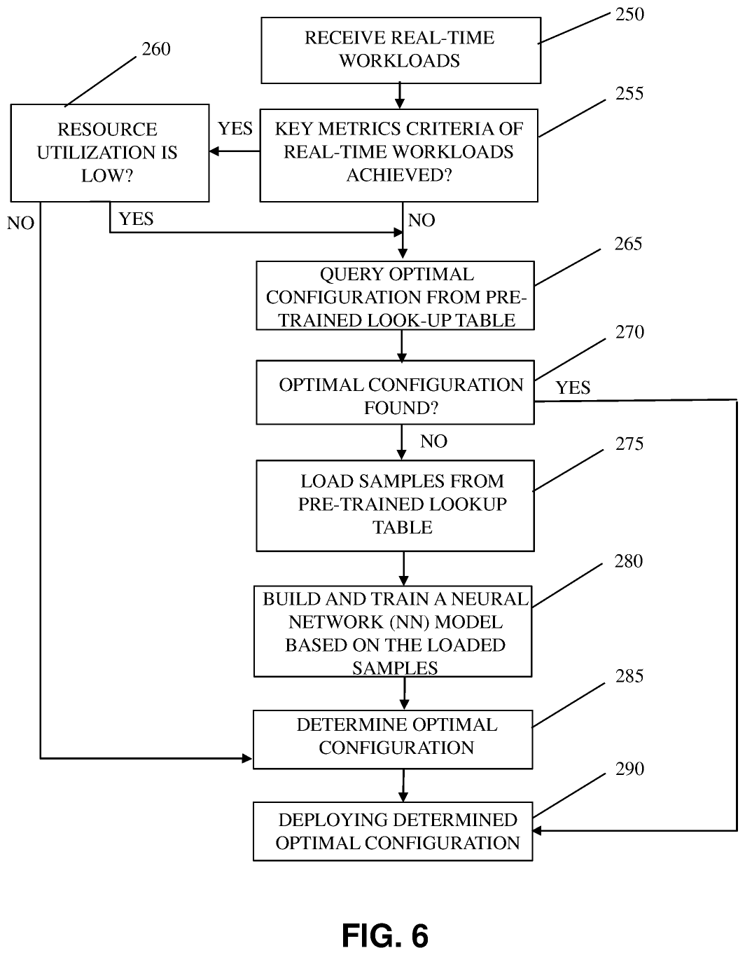

FIG. 6 shows a flowchart of an exemplary method in accordance with aspects of the present invention. Steps of the method may be carried out in the environment of FIG. 2 and are described with reference to elements depicted in FIG. 2.

At step 250, the system receives, at the production application module 216, real-time workloads from an external system. In embodiments and as described with FIG. 2, the production application module 216 comprises a production application which runs the real-time workloads and collects production telemetry data including key metrics data from the real-time workloads and sends the key metrics data to the optimization module 218.

At step 255, the system determines, at the optimization module 218, whether key metrics criteria of the real-time workloads have been achieved based on the key metrics data from the real-time workloads. At step 260, the system determines, at the optimization module 218, whether resource utilization is low in response to a determination that the key metrics criteria of the real-time workloads have been achieved. In various embodiments, if the system determines that key metrics criteria of real-time workloads have been achieved, and resource utilization is not low, then a current configuration is appropriate for an optimal configuration. Thus, the determined optimal configuration is the current configuration in step 285. In one example, after stop 260, in response to the resource utilization not being low and the key metrics criteria being achieved, the determined optimal configuration is the current configuration. Further, for those instances when the current configuration is the optimal configuration, at step 290, no new deploying is required and instead this step 290 is fulfilled by maintaining the current configuration for the real-time workloads.

At step 265, the system queries, at the optimization module 218, the optimal configuration from the pre-trained look up table 214 in response to a determination that the resource utilization is low or in response to a determination that the key metrics criteria of the real-time workloads have not been achieved. In embodiments and as described with FIG. 2, the optimization module 218 determines that the optimal configuration is found from the pre-trained look up table 214 by determining that the numerical value representing the simulated workloads associated with the optimal configuration in the pre-trained look up table 214 are within a predetermined threshold value of the received real-time workloads. At step 270, the system determines, at the optimization module 218, that the optimal configuration is found. At step 290, the system deploys, at the production application module 216, the found optimal configuration for providing resources to at least one containerized application in a containerized system response to a determination that the numerical value representing the simulated workload associated with the optimal configuration in the pre-trained look up table 214 is within a predetermined threshold value of the received real-time workloads.

At step 275, the system loads, at the optimization module 218, samples of the optimal configuration from the pre-trained look up table 214 have a numerical value which is greater than the predetermined threshold value of the received real-time workloads and have the numerical value which is less than a maximum threshold value of the received real-time workloads. In embodiments and as described with FIG. 2, the values of the predetermined threshold value and the maximum threshold value can be user configured.

At step 280, the system builds and trains, at the optimization module 218, a neural network (NN) model based on the loaded samples of the optimal configuration from the pre-trained look up table 214 which have a numerical value which is greater than the predetermined threshold value of the received real-time workloads and are have the numerical value which is less than the maximum threshold value of the received real-time workloads. At step 285, the system determines, at the optimization module 218, the optimal configuration based on the trained NN model. In embodiments and as described with FIG. 2, the optimization module 218 applies the determined optimal configuration to the real-time workloads. At step 290, the system deploys, at the production application module 216, the determined optimal configuration for providing resources to the at least one containerized application in the containerized system.

In embodiments, an entity performs the techniques described herein for their own computing configurations. In other embodiments, a service provider performs the processes described herein to help improve computing configurations for another entity. In this case, the service provider can create, maintain, deploy, support, etc., the computer infrastructure that performs the process steps of the present invention for one or more entities.

In still additional embodiments, the present invention provides a computer-implemented method, via a network. In this case, a computer infrastructure, such as computer 101 of FIG. 1, can be provided and one or more systems for performing the processes of the present invention can be obtained (e.g., created, purchased, used, modified, etc.) and deployed to the computer infrastructure. To this extent, the deployment of a system can comprise one or more of: (1) installing program code on a computing device, such as computer 101 of FIG. 1, from a computer readable medium; (2) adding one or more computing devices to the computer infrastructure; and (3) incorporating and/or modifying one or more existing systems of the computer infrastructure to enable the computer infrastructure to perform the processes of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method comprising:
comparing, by a processor set, key metrics data representing real-time workloads performed by a computer set comprising one or more containers;
determining, by the processor set, that the key metrics data does not meet key metrics criteria;
in response to the determining, querying, by the processor set, from a pre-trained look up table an optimal configuration for deploying resources to at least one containerized application of the computer set;
determining, by the processor set, that the optimal configuration is not found from the pre-trained look up table;
training, by the processor set, a neural network (NN) model by using samples from the pre-trained look up table as training data;
determining, by the processor set, the optimal configuration using the trained NN model; and
deploying, by the processor set, the determined optimal configuration for the computer set.

2. The computer-implemented method of claim 1, wherein the determining that the optimal configuration is not found from the pre-trained look up table comprises finding no matches for the key metrics data amongst entries of the pre-trained look up table.

3. The computer-implemented method of claim 1, wherein the pre-trained look up table includes entries with information representing simulated workloads.

4. The computer-implemented method of claim 3, wherein entries are added to the pre-trained look up table using a reinforcement model which is trained with a reinforcement algorithm using the simulated workloads.

5. The computer-implemented method of claim 4, wherein the reinforcement algorithm comprises a Q learning algorithm.

6. The computer-implemented method of claim 5, wherein the Q learning algorithm dynamically captures states of containerized applications based on key metrics data of the simulated workloads and dynamically generates action lists for the containerized applications based on the key metrics data and a service topology of the simulated workloads.

7. The computer-implemented method of claim 6, wherein the Q learning algorithm creates one or more Q tables of the simulated workloads.

8. The computer-implemented method of claim 7, wherein the simulated workloads produce pre-production data which includes data that is used for performance evaluation and testing.

9. The computer-implemented method of claim 1, wherein the real-time workloads produce production data which includes real-time data.

10. The computer-implemented method of claim 1, further comprising selecting the samples from the pre-trained look up table to use as the training data by identifying the samples with computing values which are greater than a predetermined threshold value of the computing values of the received real-time workloads and are less than a maximum threshold value of the computing values of the received real-time workloads.

11. The computer-implemented method of claim 1, wherein the training data is used for supervised learning of the NN model.

12. A computer program product comprising one or more computer readable storage media having program instructions collectively stored on the one or more computer readable storage media, the program instructions executable to: receive real-time workloads from an external system;
determine that key metrics criteria of the real-time workloads have not been achieved;
query an optimal configuration from a pre-trained look up table;
determine that the optimal configuration is not found from the pre-trained look up table;
load samples from the pre-trained look up table;
train a neural network (NN) model based on the loaded samples of the optimal configuration from the pre-trained look up table;
determine the optimal configuration using the trained NN model; and
deploy the determined optimal configuration for providing resources to at least one containerized application in a containerized system.

13. The computer program product of claim 12, wherein the determining that the optimal configuration is not found from the pre-trained look up table comprises determining that simulated workloads associated with the optimal configuration in the pre-trained look up table are greater than a predetermined threshold value of the received real-time.

14. The computer program product of claim 12, wherein the loading the samples from the pre-trained look up table comprises loading the samples which are greater than a predetermined threshold value of the received real-time workloads and are less than a maximum threshold value of the received real-time workloads.

15. The computer program product of claim 12, wherein the program instructions are executable to apply the determined optimal configuration to the real-time workloads.

16. The computer program product of claim 12, wherein the pre-trained look up table is pre-trained using a reinforcement model which is trained using a reinforcement algorithm of simulated workloads.

17. The computer program product of claim 16, wherein the reinforcement algorithm comprises a Q learning algorithm.

18. The computer program product of claim 17, wherein the Q learning algorithm dynamically captures states based on the key metrics data of the simulated workloads and dynamically generates action lists based on the key metrics data and a service topology of the simulated workloads.

19. The computer program product of claim 18, wherein the simulated workloads comprise pre-production data which includes data that is used for performance evaluation and testing.

20. A system comprising:
a processor set, one or more computer readable storage media, and program instructions, collectively stored on the one or more computer readable storage media, for causing the processor set to:
receive simulated workloads from an external system, the simulated workloads simulating performance of at least one containerized application;
train a reinforcement learning model based on the simulated workloads;
determine one or more optimal configurations using the trained reinforcement learning model and the simulated workloads; and
store entries representing the one or more optimal configurations in a pre-trained look up table,
wherein the simulated workloads produce pre-production data which includes data that is used for performance evaluation and testing, and wherein the pre-trained look-up table is accessible for providing recommendations for configurations for applying computing resources to a containerized application.
